(19) United States
(12) Patent Application Publication
(10) Pub. No.: US 2021/0246568 A1
(43) Pub. Date: Aug. 12, 2021

(54) ROTATING FIXTURE FOR PLATING PLATES

(71) Applicant: Minhou Forao Arts&Crafts Co., Ltd, Fujian (CN)

(72) Inventor: Baiyue Huang, Fujian (CN)

(21) Appl. No.: 16/788,055

(22) Filed: Feb. 11, 2020

(51) Int. Cl. C25D 17/08

(52) U.S. Cl. CPC C25D 17/08

(57) ABSTRACT

A rotating fixture for plating plates is disclosed. The rotating fixture includes a rotating shaft, capable of installing in a plating compartment of a plating equipment and rotationally connecting thereto; a mounting rack, fixed on a periphery of the rotating shaft, synchronously rotating with the rotating shaft; and at least one fixture component, installed on the mounting rack, clamping plates. The fixture is rotationally connected to the plating compartment. During plating, uniform speed can be driven by external force to overcome the disadvantages of uneven plating. Meanwhile, plates are clamped by multiple sets of fixture components. It is able to hold multiple plates and hold firmly.

### FIELD OF THE INVENTION

The present invention relates to a fixture. More particularly, the present invention relates to a rotating fixture for plating plates.

### BACKGROUND OF THE INVENTION

In traditional plate plating processes, when a plate is under plating, it is to stick the back of the plate directly on the shelf, and then put it into the plating compartment of plating equipment for plating. This will cause the following problems: 1. since the plate is bonded to the shelf, if the fastening effect is good, it is difficult to remove it in the later stage; if the fastening effect is poor, it is likely to fall off during the plating process, and the bonding part cannot be plated; 2. since the plate is fixed in the plating equipment, the phenomenon of uneven plating will occur; 3. limited number of single-use bonding plates cannot meet high industrial efficiency needs.

### SUMMARY OF THE INVENTION

The purpose of the present invention is to overcome the above disadvantages and provide a rotating fixture for plating plates. The fixture can rotationally connect to a plating compartment of a plating equipment by a rotating shaft. During plating, uniform speed can be driven by external force to overcome the disadvantages of uneven plating on the plate. Meanwhile, multiple sets of fixture components can be used to clamp multiple plates as required. It has a large amount of clamping, stable clamping, convenient assembly and disassembly, and is conducive to improving production efficiency.

The present invention is achieved through the following technical solution. a rotating fixture for plating plates comprises: a rotating shaft capable of installing in a plating compartment of a plating equipment and rotationally connecting thereto; a mounting rack, which is fixed on a periphery of the rotating shaft, synchronously rotating with the rotating shaft; and at least one fixture component, which is installed on the mounting rack, clamping plates. The plate is a plastic plate and made by spraying Polypropylene (PP) paint on a surface of an injection-molded plastic substrate. The rotating fixture for plating plates and the plates are placed in the plating compartment of the plating equipment for plating. During the plating processes, the rotating shaft is rotated and metal wires in the plating compartment is heated by the plating compartment. Air pressure in the plating compartment is substantially close to vacuum. When the metal wires are heated to the volatilization temperature. Volatilized metal is attached to the surface of the injection-molded plastic substrate. The plates are removed from the at least one fixture component to be protected by spraying a layer of protective paint over the surface of the injection-molded plastic substrate.

To better implement this solution, the following optimized solutions are also provided. To facilitate the rotation of the fixture, the rotating fixture for plating further comprises: mounting seats, installed in the plating compartment, wherein the rotating shaft is rotationally connected to the mounting seats; and a rotationally driving component, connected between the mounting seat and the rotating shaft, driving the rotating shaft.

To facilitate the installation of the plate on the fixture and to facilitate the removal of the plate from the fixture, each fixture component comprises at least three elastically pressing rods, arranged along a circle and at different locations of a circumference of the circle, clamping a periphery of the plate to hold the plate, and a center angle corresponding to an arc formed by linking locations on the periphery of the plate pressed and contacted by all elastically pressing rods is greater than 180 degrees.

To facilitate stable plate clamping, one end of each elastically pressing rod is fixed on the mounting rack and the other end forms a pressing section which is V-shaped, and V-shaped recesses of the pressing sections of all elastically pressing rods all face the periphery of the held plate and elastically clamp the periphery of the plate.

To facilitate the clamping of different size plates, each fixture component further comprises a base rod which is removably mounted on the mounting rack, and a first mounting rod and a second mounting rod which are interleavedly installed on an outside of the base rod and parallel to each other. The first mounting rod and the second mounting rod are both perpendicular to the base rod. A number of the elastically pressing rods is three or four. One of the first mounting rod and the second mounting rod has two elastically pressing rods and the other has one or two elastically pressing rods. The location of at least one of the first mounting rod and the second mounting rod is adjustable related to the base rod.

Preferably, an axis of the base rod is parallel to that of the rotating shaft. The first mounting rod and the second mounting rod are installed on two ends of the base rod, respectively. A chute is formed through the longitudinal direction of the base rod. The base rod is fixed on the mounting rack by at least two sets of bolt and nut through the chute. The first mounting rod is fixed on a lower end of the base rod. The second mounting rod is removably mounted on base rod by the set of bolt and nut on an upper end.

To facilitate the installation of fixture component, the mounting rack comprises: a first mounting seat fixed on one end of the rotating shaft, a second mounting seat fixed on the other end of the rotating shaft and at least one connecting rod connecting the first mounting seat and the second mounting seat and parallel to the rotating shaft. The connecting rod sequentially has a plurality of mounting holes formed to vertically penetrate the connecting rod for mounting the fixture component along the longitudinal direction. When the number of the connecting rods is greater than two, the connecting rods are evenly distributed along the circumference of the rotating shaft.

To easily disassemble of the connecting rod, the first mounting seat has mounting slots with the same amount as the connecting rods. When the number of the mounting slots is more than one, the mounting slots are distributed around a circumference of a circle centered at the rotating shaft. The second mounting seat has mounting through holes with locations and quantities corresponding to the mounting slots. One end of the connecting rod is inserted into the mounting slot and the other end is extended upward and through the mounting through hole.

To easily adjust the position of the connecting rod, the first mounting seat further sequentially has at least one adjusting slot on each mounting slot along the same radial direction related to the rotating shaft, and the second mounting seat has adjusting through holes with locations and quantities corresponding to the adjusting slots.

Preferably, the first mounting seat comprises a first mounting seat body and a plurality of third mounting rods which has one end connected to the first mounting seat body and the other end extended along a radial direction of the rotating shaft. The mounting slot and the adjusting slot along the same radial direction are formed on a third mounting rod. The second mounting seat comprises a second mounting seat body and fourth mounting rods with locations and quantities corresponding to third mounting rods. The mounting through hole and the adjusting through hole along the same radial direction are formed on a fourth mounting rod.

The PP paint comprises 3-5 weight parts of advanced acrylic resin, 3-5 weight parts of organic silicone resin, 1-2 weight parts of pigments, 1-2 weight parts of adjuvant and 1-3 weight parts of solvent. The metal wires are made of aluminum, copper, silver, chromium or alloy. The air pressure is 5×10⁻² Pa. The protective paint is anti-rust paint. The plates are baked after being sprayed the layer of protective paint. The temperature of the plating compartment is 80-90° C. and a time for baking is 80-100 minutes.

Compared with the prior arts, the beneficial effects of the present invention are listed below.

1. A rotating fixture for plating plates is provided in the present invention. The fixture is rotationally connected to the plating compartment. During plating, uniform speed can be driven by external force to overcome the disadvantages of uneven plating. Meanwhile, plates are clamped by multiple sets of fixture components. It is able to hold multiple plates and hold firmly.

2. In the present invention, the rotating shaft is rotationally connected to mounting seat. There are also rotationally driving components connected between the mounting seat and the rotating shaft to drive the rotating shaft. It ensures that the rotating shaft can rotate evenly.

3. In the present invention, each fixture component comprises at least three elastically pressing rods which are arranged along a circle and at different locations of a circumference of the circle and clamp the periphery of the plate to hold the plate, and the center angle corresponding to an arc formed by linking locations on the periphery of the plate pressed and contacted by all elastically pressing rods is greater than 180 degrees. Due to the elasticity of the elastically pressing rod, the installation and removal of the plates are very convenient. It only holds the top of the plate with hand and press the elastically pressing rod on one side, loading and unloading can be operated.

4. In the present invention, one end of each elastically pressing rod has a pressing section which is V-shaped. V-shaped recess of the pressing sections of all elastically pressing rods all face the periphery of the held plate and elastically clamp the periphery of the plate. It ensures that the fixture can hold the plate firmly.

5. In the present invention, at least one of the first mounting rod and the second mounting rod is adjustable in position related to base rod. By adjusting the relative position between the two, the clamping space enclosed between the elastically pressing rods can be made larger and smaller to accommodate plates of different sizes. It enables the fixture to clamp plates of different diameters.

6. In the present invention, to facilitate the installation of fixture components, there is at least one connecting rod between the first mounting seat and the second mounting seat. The connecting rod has mounting holes. At least one fixture component is fixed on the mounting rack through the mounting holes. When the number of the connecting rods is more than one, the connecting rods are evenly distributed along the circumference of the rotating shaft. It ensures the stability of the fixture.

7. In the present invention, the first mounting seat has mounting slots and the second mounting seat has mounting through holes. One end of the connecting rod is inserted to the bottom of the mounting slot while the other end is extended upward and through the mounting through hole. The connecting rod can be pulled upwards. The subsequent repairs and replacements are very convenient.

8. In the present invention, each mounting slot also sequentially has at least one adjusting slot. Each mounting through hole also sequentially has at least one adjusting through hole. The connecting rod can be replaced between the corresponding adjusting slot and adjusting through hole to accommodate different diameter plates. When the diameter of the plate is large, the connecting rod needs to be adjusted outward in the radial direction of the rotating shaft, avoiding interference between plates clamped by the fixture components.

9. In the present invention, the first mounting seat comprises the first mounting seat body and the third mounting rod. The second mounting seat comprises the second mounting seat body and the fourth mounting rod. The first mounting seat body and the second mounting seat body are fixed on the rotating shaft by means of pins. This design reduces the weight of the entire fixture and reduces manufacturing costs.

10. The invention also has the advantages of convenient use and convenient operation.

The plates coated by the rotating fixture has the advantages below.

1. No pickling is required.

2. A series of processes of brushing, foiling, foil removing, and polishing, which greatly reduces the manufacturing process, thereby reducing the manufacturing cost, are eliminated.

3. Physical damages to operators due to the large amount of dust generated during production can be avoided.

4. Defective rate is reduced and product quality is improved.

5. The plates can produce a very bright mirror effect.

### BRIEF DESCRIPTION OF THE DRAWINGS

FIG. 1 is a structural diagram according to the present invention.

FIG. 2 is an exploded view of the present invention.

FIG. 3 is a structural diagram of a base rod, a first mounting rod, and an elastically pressing rod in the present invention.

FIG. 4 is a structural diagram of a second mounting rod and an elastically pressing rod in the present invention.

FIG. 5 is a structural diagram of a first mounting seat in the present invention.

FIG. 6 is a structural diagram of a second mounting seat in the present invention.

### DETAILED DESCRIPTION OF THE PREFERRED EMBODIMENTS

The present invention is described in detail below with reference to the drawings.

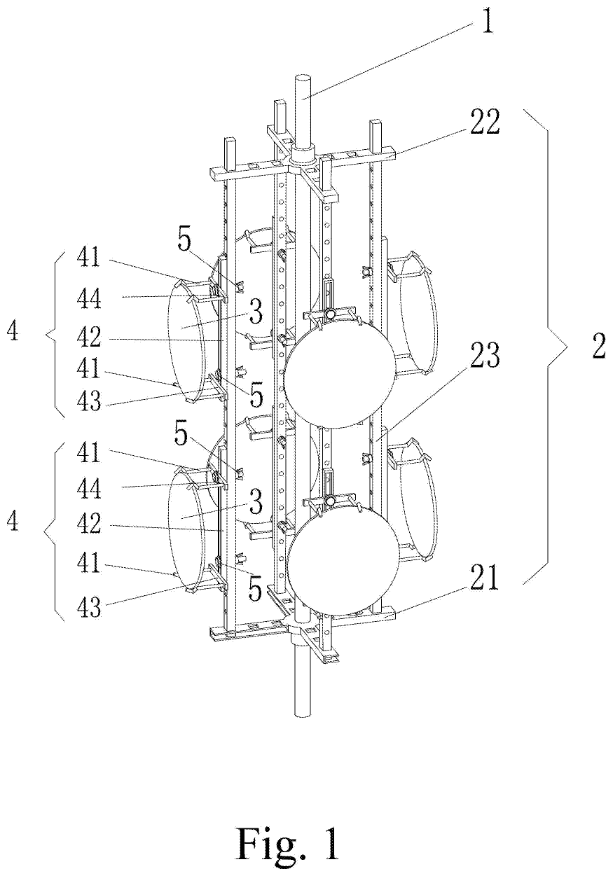

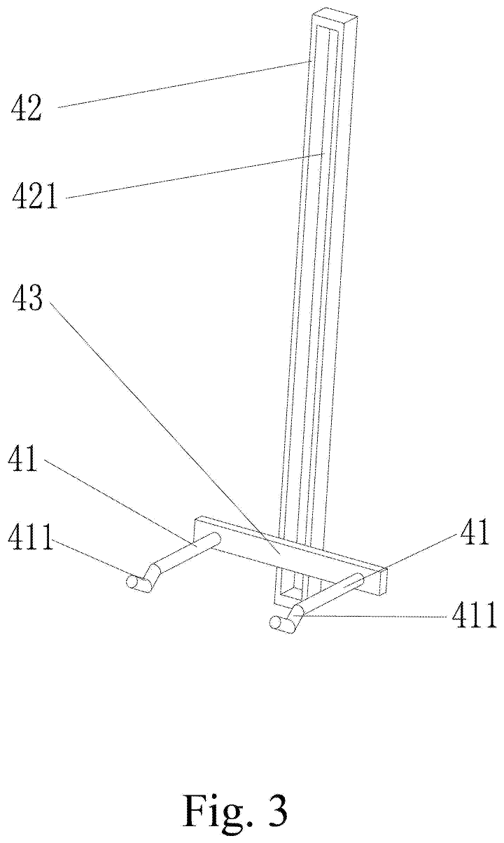

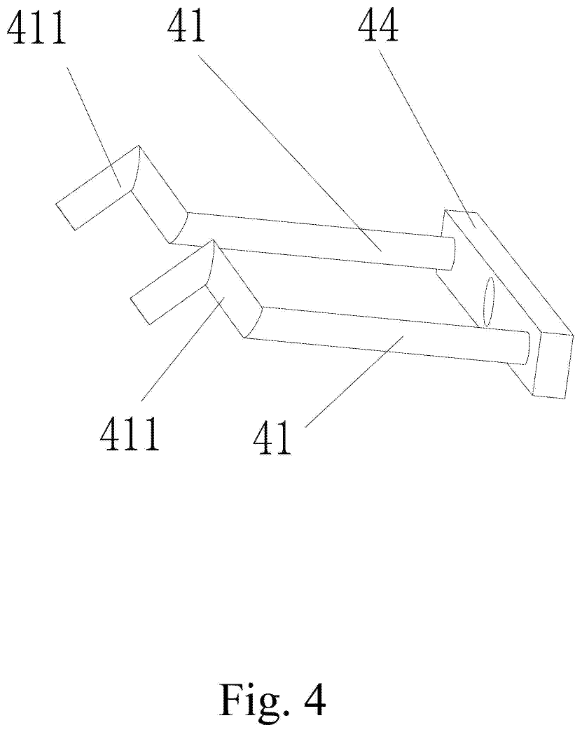

As shown in FIG. 1 to FIG. 6, the present invention includes a rotating shaft 1 which is capable of installing in a plating compartment of a plating equipment and rotationally connecting thereto, a mounting rack 2 which is fixed on a periphery of the rotating shaft 1 and synchronously rotates with the rotating shaft a and at least one fixture component 4 which is installed on the mounting rack 2 to clamp plates 3.

To co-work with the plating compartment of the plating equipment, the plate 3 can be a plastic plate and made by spraying PP paint on a surface of an injection-molded plastic substrate. The rotating fixture for plating plates and the plates 3 are placed in the plating compartment of the plating equipment for plating. During the plating processes, the rotating shaft 1 is rotated by the plating compartment and metal wires in the plating compartment is heated by the heating device, such as heating tungsten wires, of the plating compartment. Air pressure in the plating compartment is substantially close to vacuum. When the metal wires are heated to the volatilization temperature. Volatilized metal is attached to the surface of the injection-molded plastic substrate to form a shiny surface. The plates 3 are removed from the at least one fixture component to be protected by spraying a layer of protective paint over the surface of the injection-molded plastic substrate.

To facilitate the rotation of the fixture, the rotating fixture for plating plates further comprises mounting seats which is installed in the plating compartment. The rotating shaft 1 is rotationally connected to the mounting seat. The rotating fixture for plating plates also comprises a rotationally driving component which is connected between the mounting seat and the rotating shaft 1 to drive the rotating shaft 1. The driving component may include a motor, a reducer, and a gear mechanism.

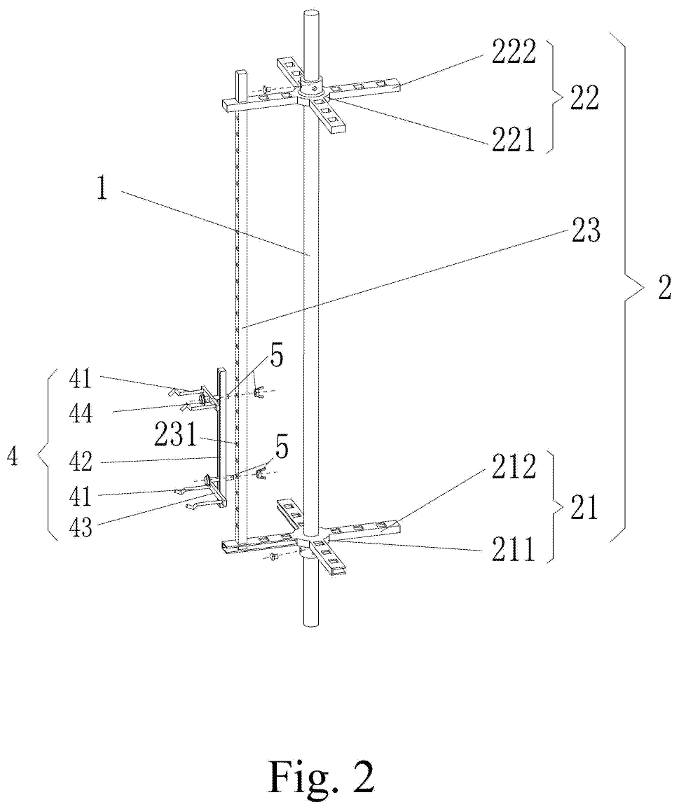

As shown in FIG. 1 to FIG. 2, to easily install the plate on this fixture and easily remove the plate from the fixture, each fixture component 4 comprises at least three elastically pressing rods 41 which are arranged along a circle and at different locations of a circumference of the circle and can clamp a periphery of the plate 3 to hold the plate 3. A center angle corresponding to an arc formed by linking locations on the periphery of the plate pressed and contacted by all elastically pressing rods 41 is greater than 180 degrees.

As shown in FIG. 1 to FIG. 4, to facilitate stable plate clamping, one end of each elastically pressing rod 41 is fixed on the mounting rack 2 and the other end forms a pressing section 411 which is V-shaped. V-shaped recesses of the pressing sections of all elastically pressing rods 411 all face the periphery of the held plate 3 and elastically clamp the periphery of the plate 3.

As shown in FIG. 1 to FIG. 4, to facilitate the clamping of different size plates, each fixture component 4 further comprises a base rod 42 which is removably mounted on the mounting rack 2, and a first mounting rod 43 and a second mounting rod 44 interleavedly installed on an outside of the base rod 42 and parallel to each other. The first mounting rod 43 and the second mounting rod 44 are both perpendicular to the base rod 42. A number of the elastically pressing rods 41 is three or four. One of the first mounting rod 43 and the second mounting rod 44 has two elastically pressing rods 41 and the other has one or two elastically pressing rods 41. The location of at least one of the first mounting rod 43 and the second mounting rod 44 is adjustable related to the base rod 42.

As shown in FIG. 1 to FIG. 4, preferably, an axis of the base rod 42 is parallel to that of the rotating shaft 1. The first mounting rod 43 and the second mounting rod 44 are installed on two ends of the base rod 42, respectively. A chute 421 is formed through the longitudinal direction of the base rod 42. The base rod 42 is fixed on the mounting rack by at least two sets of bolt and nut 5 through the chute 421. The first mounting rod 43 is fixed on a lower end of the base rod 42. The second mounting rod 43 is removably mounted on base rod 42 by the set of bolt and nut 5 on an upper end.

As shown in FIG. 1 to FIG. 2, to facilitate the installation of fixture components, the mounting rack 2 comprises a first mounting seat 21 fixed on one end of the rotating shaft 1, a second mounting seat 22 fixed on the other end of the rotating shaft 1 and at least one connecting rod 23 connecting the first mounting seat 21 and the second mounting seat 22 and parallel to the rotating shaft 1. The connecting rod 23 sequentially has a number of mounting holes 231 formed to vertically penetrate the connecting rod 23 for mounting the fixture component 4 along the longitudinal direction. When the number of the connecting rods 23 is greater than two, the connecting rods 23 are evenly distributed along the circumference of the rotating shaft 1.

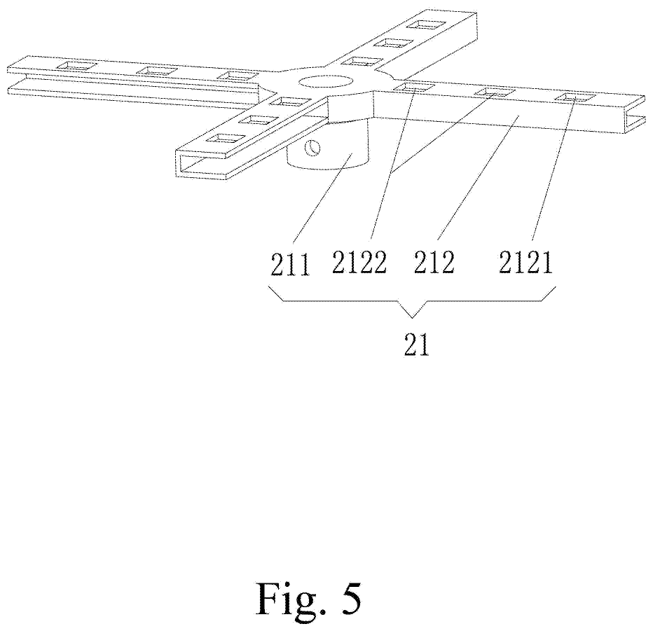

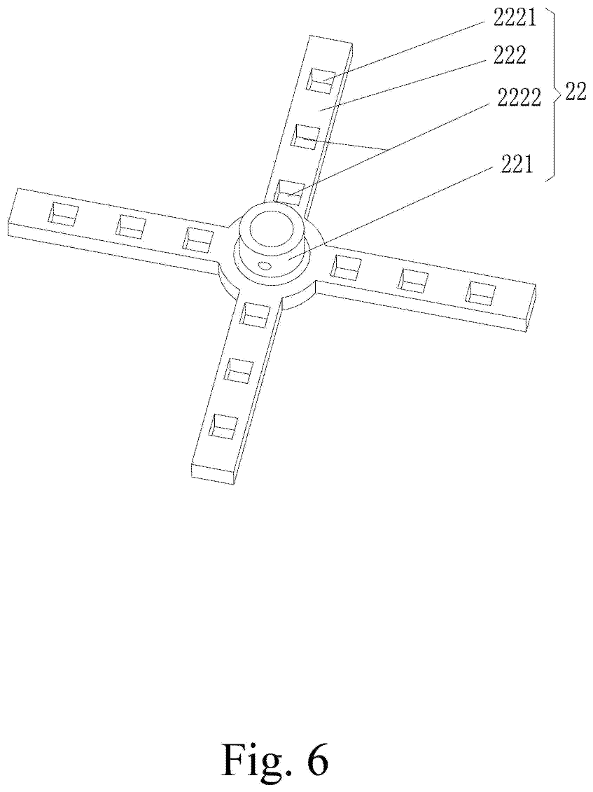

As shown in FIG. 1, FIG. 2, FIG. 5 and FIG. 6, to easily disassemble the connecting rod, the first mounting seat 21 has mounting slots 2121 with the same amount as the connecting rods 23. When the number of the mounting slots 2121 is more than one, the mounting slots 2121 are distributed around a circumference of a circle centered at the rotating shaft 1. The second mounting seat 22 has mounting through holes 2221 with locations and quantities corresponding to the mounting slots 2121. One end of the connecting rod 23 is inserted into the mounting slot 2121 and the other end is extended upward and through the mounting through hole 2221.

As shown in FIG. 1, FIG. 2, FIG. 5 and FIG. 6, preferably, the first mounting seat 21 further sequentially has at least one adjusting slot 2122 on each mounting slot 2121 along the same radial direction related to the rotating shaft 1. The second mounting seat 22 has adjusting through holes 2222 with locations and quantities corresponding to the adjusting slots 211.

As shown in FIG. 1, FIG. 2, FIG. 5 and FIG. 6, preferably, the first mounting seat 21 comprises a first mounting seat body 211 and a number of third mounting rods 212 which has one end connected to the first mounting seat body 211 and the other end extended along a radial direction of the rotating shaft 1. The mounting slot 2121 and the adjusting slot 2122 along the same radial direction are formed on a third mounting rod 212. The second mounting seat 22 comprises a second mounting seat body 221 and fourth mounting rods 222 with locations and quantities corresponding to the third mounting rods 212. The mounting through hole 2221 and the adjusting through hole 2222 along the same radial direction are formed on a fourth mounting rod 222.

Working principles of the invention are described below. The rotating fixture for plating plates provided by the present invention is applicable to the plating process of a plate. The rotating shaft in the fixture 1 is rotationally connected to the plating compartment. The rotationally driving component drives the entire fixture and the clamped plate 3 to rotate, so that the plate 3 and the electrolyte can contact uniformly, avoiding the phenomenon of uneven plating on the plate. A number of the connecting rod 23 in the fixture may be one or more. When the number of the connecting rods 23 is two or more, they are evenly distributed along the axial direction of rotating shaft 1, so that the fixture can adapt to faster rotation speed without losing stability. When there is one connecting rod 23, as long as the rotation speed is controlled within a proper range, the fixture can also drive the plate 3 to rotate. It also ensures that there is no uneven plating. Each connecting rod 23 in the fixture is installed at least one fixture component 4. Such design greatly increases the amount of clamping of the fixture and improves the production efficiency of plate plating. The location of the second mounting rod 44 in the fixture component 4 is adjustable related to the base rod 42. The distance between the two elastically pressing rods 41 on the second mounting rod 44 and the distance between the two elastically pressing rods 41 on the first mounting rod 212 will be changed during the adjustment to fit different sizes of the plate 3. After the locations are adjusted, fix the second mounting rod 44 by the set of bolt and nut 5. The base rod 42 is fixed on the connecting rod 23 by two sets of bolt and nut 5 penetrating the chute 421. Due to the elasticity of the elastically pressing rod 41, the installation and removal of the plate 3 are very convenient. It only holds the top of the plate 3 with hand and press the elastically pressing rod 41 on one side, loading and unloading can be operated.

The PP paint comprises 3-5 weight parts of advanced acrylic resin, 3-5 weight parts of organic silicone resin, 1-2 weight parts of pigments, 1-2 weight parts of adjuvant and 1-3 weight parts of solvent. According to the present invention, the metal wires may be made of aluminum, copper, silver, chromium or alloy. The air pressure is better at 5×10⁻² Pa. The protective paint is anti-rust paint. The plates are baked after being sprayed the layer of protective paint. The temperature of the plating compartment is 80˜90° C. and a time for baking is 80˜100 minutes.

Although the present invention uses specific embodiments and alternatives to illustrate and explain the present invention, it should be understood that various changes and modifications can be implemented without departing from the spirit of the present invention. Therefore, it should be understood that the present invention is not limited in any sense except by the appended claims and their equivalents.

What is claimed is:

1. A rotating fixture for plating plates, comprising:
a rotating shaft, capable of installing in a plating compartment of a plating equipment and rotationally connecting thereto;
a mounting rack, fixed on a periphery of the rotating shaft, synchronously rotating with the rotating shaft; and
at least one fixture component, installed on the mounting rack, clamping plates,
wherein the plate is a plastic plate and made by spraying Polypropylene (PP) paint on a surface of an injection-molded plastic substrate, the rotating fixture for plating plates and the plates are placed in the plating compartment of the plating equipment for plating, during the plating processes, the rotating shaft is rotated and metal wires in the plating compartment is heated by the plating compartment, air pressure in the plating compartment is substantially close to vacuum, when the metal wires are heated to the volatilization temperature, volatilized metal is attached to the surface of the injection-molded plastic substrate, and the plates are removed from the at least one fixture component to be protected by spraying a layer of protective paint over the surface of the injection-molded plastic substrate.

2. The rotating fixture for plating plates according to claim 1, further comprising:
mounting seats, installed in the plating compartment, wherein the rotating shaft is rotationally connected to the mounting seats; and
a rotationally driving component, connected between the mounting seat and the rotating shaft, driving the rotating shaft.

3. The rotating fixture for plating plates according to claim 1, wherein each fixture component comprises at least three elastically pressing rods, arranged along a circle and at different locations of a circumference of the circle, clamping a periphery of the plate to hold the plate, and a center angle corresponding to an arc formed by linking locations on the periphery of the plate pressed and contacted by all elastically pressing rods is greater than 180 degrees.

4. The rotating fixture for plating plates according to claim 3, wherein one end of each elastically pressing rod is fixed on the mounting rack and the other end forms a pressing section which is V-shaped, and V-shaped recesses of the pressing sections of all elastically pressing rods all face the periphery of the held plate and elastically clamp the periphery of the plate.

5. The rotating fixture for plating plates according to claim 3, wherein each fixture component further comprises a base rod, removably mounted on the mounting rack, and a first mounting rod and a second mounting rod interleavedly installed on an outside of the base rod and parallel to each other, the first mounting rod and the second mounting rod are both perpendicular to the base rod, a number of the elastically pressing rods is three or four, one of the first mounting rod and the second mounting rod has two elastically pressing rods and the other has one or two elastically pressing rods, and the location of at least one of the first mounting rod and the second mounting rod is adjustable related to the base rod.

6. The rotating fixture for plating plates according to claim 5, wherein an axis of the base rod is parallel to that of the rotating shaft, the first mounting rod and the second mounting rod are installed on two ends of the base rod, respectively, a chute is formed through the longitudinal direction of the base rod, the base rod is fixed on the mounting rack by at least two sets of bolt and nut through the chute, the first mounting rod is fixed on a lower end of the base rod, and the second mounting rod is removably mounted on base rod by the set of bolt and nut on an upper end.

7. The rotating fixture for plating plates according to claim 1, wherein the mounting rack comprises: a first mounting seat fixed on one end of the rotating shaft, a second mounting seat fixed on the other end of the rotating shaft and at least one connecting rod connecting the first mounting seat and the second mounting seat and parallel to the rotating shaft, the connecting rod sequentially has a plurality of mounting holes formed to vertically penetrate the connecting rod for mounting the fixture component along the longitudinal direction, when the number of the connecting rods is greater than two, the connecting rods are evenly distributed along the circumference of the rotating shaft.

8. The rotating fixture for plating plates according to claim 7, wherein the first mounting seat has mounting slots with the same amount as the connecting rods, when the number of the mounting slots is more than one, the mounting slots are distributed around a circumference of a circle centered at the rotating shaft, the second mounting seat has mounting through holes with locations and quantities corresponding to the mounting slots, and one end of the connecting rod is inserted into the mounting slot and the other end is extended upward and through the mounting through hole.

9. The rotating fixture for plating plates according to claim 8, wherein the first mounting seat further sequentially has at least one adjusting slot on each mounting slot along the same radial direction related to the rotating shaft, and the second mounting seat has adjusting through holes with locations and quantities corresponding to the adjusting slots.

10. The rotating fixture for plating plates according to claim 9, wherein the first mounting seat comprises a first mounting seat body and a plurality of third mounting rods which has one end connected to the first mounting seat body and the other end extended along a radial direction of the rotating shaft, the mounting slot and the adjusting slot along the same radial direction are formed on a third mounting rod, the second mounting seat comprises a second mounting seat body and fourth mounting rods with locations and quantities corresponding to third mounting rods, and the mounting through hole and the adjusting through hole along the same radial direction are formed on a fourth mounting rod.

11. The rotating fixture for plating plates according to claim 1, wherein the PP paint comprises 3-5 weight parts of advanced acrylic resin, 3-5 weight parts of organic silicone resin, 1-2 weight parts of pigments, 1-2 weight parts of adjuvant and 1-3 weight parts of solvent.

12. The rotating fixture for plating plates according to claim 1, wherein the metal wires are made of aluminum, copper, silver, chromium or alloy.

13. The rotating fixture for plating plates according to claim 1, wherein the air pressure is 5×10⁻² Pa.

14. The rotating fixture for plating plates according to claim 1, wherein the protective paint is anti-rust paint.

15. The rotating fixture for plating plates according to claim 1, wherein the plates are baked after being sprayed the layer of protective paint.

16. The rotating fixture for plating plates according claim 15, wherein the temperature of the plating compartment is 80˜90° C. and a time for baking is 80˜100 minutes.
